(19) United States
(12) Patent Application Publication
(10) Pub. No.: US 2013/0264609 A1
(43) Pub. Date: Oct. 10, 2013

(54) Semiconductor Structure of Hybrid of Coplanar Ge and III-V and Preparation Method Thereof

(71) Applicants: Zengfeng Di, Shanghai (CN); Jiantao Bian, Shanghai (CN); Miao Zhang, Shanghai (CN); Xi Wang, Shanghai (CN)

(72) Inventors: Zengfeng Di, Shanghai (CN); Jiantao Bian, Shanghai (CN); Miao Zhang, Shanghai (CN); Xi Wang, Shanghai (CN)

(21) Appl. No.: 13/636,127

(22) PCT Filed: May 16, 2012
(86) PCT No.: PCT/CN12/75550

§ 371 Date: Sep. 20, 2012

(30) Foreign Application Priority Data
May 16, 2011 (CN) 201110126394.1

(51) Int. Cl. H01L 29/66; H01L 29/778

(52) U.S. Cl. CPC H01L 29/66431; H01L 29/7786
USPC 257/195; 438/222

(57) ABSTRACT

The present invention provides a semiconductor structure with a hybrid of Ge and a group III-V material coplanar and a preparation method thereof. A heterogeneously integrated semiconductor structure with Ge and a group III-V semiconductor material coplanar includes at least one Ge substrate formed on a bulk silicon substrate, and the other substrate is the group III-V semiconductor material formed on the Ge semiconductor. The preparation method includes: preparing a Ge semiconductor layer on a bulk silicon substrate; preparing a group III-V semiconductor material layer on the Ge semiconductor layer; performing first photolithography and etching to make a patterned window to a Ge layer so as to form a recess; preparing a spacer in the recess; preparing a Ge film through selective epitaxial growth; performing chemical mechanical polishing to obtain a heterogeneously integrated semiconductor structure with a hybrid of Ge and the group III-V semiconductor material coplanar; removing the spacer and a defect part of the Ge layer close to the spacer; implementing isolation between Ge and the group III-V semiconductor material; and preparing a high performance CMOS device including a Ge channel PMOS and a group III-V channel NMOS by forming an MOS structure.

### BACKGROUND OF THE PRESENT INVENTION

1. Field of Invention

The present invention relates to the field of semiconductor manufacturing, and more specifically, the present invention relates to a coplanarly and heterogeneously integrated semiconductor structure, and especially to a heterogeneously integrated substrate material of Ge and a group III-V semiconductor material coplanar on a bulk silicon substrate, and a high performance CMOS device manufactured according to the semiconductor structure.

2. Description of Related Arts

With the development of a semiconductor technology, especially when the device characteristic dimension scales down to 22 nm node technology or beyond, a semiconductor material of high mobility needs to be adopted, such as germanium (Ge), a group III-V semiconductor material and the like. Ge has high electron mobility and hole mobility. However, due to the limitation of device process factors (n-type doping and n-type ohmic contact of Ge and the like), performance of an N-type metal oxide semiconductor (NMOS) of Ge is always undesirable. The group III-V semiconductor material such as GaAs has high electron mobility and is capable of manufacturing a NMOS device with high performance.

According to the International Roadmap for Semiconductor (ITRS), a heterogeneously integrated semiconductor substrate material of high mobility with both a group III-V material and a Ge material on an insulator or a silicon substrate should be developed to ensure that the integrated circuit technology continuously develops along or beyond the Moore's law. At the same time, the heterogeneously integrated semiconductor substrate material of high mobility with both a group III-V material and a Ge material on an insulator or a silicon substrate may also be developed to provide high performance substrate materials for implementing integration multifunctional chips such as the monolithic optoelectronic integrated chip and MEMS.

However, there is no feasible CMOS device manufacturing method for implementing high performance CMOS devices on a silicon substrate structure with a hybrid of Ge and a group III-V semiconductor material coplanar. The group III-V (compounds) semiconductor material refers to a compound formed by a group III element (such as B, Al, Ga, or In) and a group V element (such as N, P, AS, or Sb) in the periodic table of elements.

Therefore, it is expected to propose a method for preparing a heterogeneously integrated substrate with a hybrid of Ge and a group III-V semiconductor material coplanar on a bulk silicon substrate, and a method for preparing the structure of the substrate; further implement a CMOS device with high performance on the substrate.

### SUMMARY OF THE PRESENT INVENTION

Therefore, an object of the present invention is providing a method for preparing a heterogeneously integrated substrate with a hybrid of Ge and a group III-V semiconductor material coplanar on a bulk silicon substrate and a structure thereof, and a CMOS device with high performance prepared according to the substrate and the structure thereof.

According to a first aspect of the present invention, a heterogeneously integrated semiconductor structure with a hybrid of Ge and a group III-V semiconductor material coplanar on a bulk silicon substrate is provided, and particularly, a heterogeneously integrated substrate material with a hybrid of Ge and a group III-V semiconductor material mixed and coplanar on a bulk silicon substrate and a method for preparing the substrate thereof are provided.

In the heterogeneously integrated substrate material with Ge and the group III-V semiconductor material coplanar on the bulk silicon substrate consistent with the present invention, a silicon support substrate, a Ge semiconductor layer, a group III-V semiconductor material layer, and an isolation medium material between Ge and the group III-V semiconductor material are disposed. The Ge semiconductor layer is located on the silicon support substrate. The group III-V semiconductor material layer is located on a part of the Ge semiconductor layer. A top of the group III-V semiconductor material layer is coplanar with the Ge semiconductor layer laterally adjacent to the group III-V semiconductor material layer, the isolation medium material between Ge and the group III-V semiconductor material is located on the bulk silicon substrate, and a lateral structure is that two sides of the isolation medium material are connected to the Ge semiconductor layer and the group III-V semiconductor material respectively.

The semiconductor structure consistent with the present invention comprises the substrate material consistent with the present invention, and at least two kinds of devices are comprised, wherein at least one of the devices is located on the Ge semiconductor layer, and the other device is located on the group III-V semiconductor material layer.

The preparation method consistent with the present invention comprises: preparing a Ge semiconductor layer on a bulk silicon substrate; preparing a group III-V semiconductor material layer on the Ge semiconductor layer; performing first photolithography and etching a patterned window to the Ge layer so as to form a recess; preparing a spacer in the recess; preparing a Ge film through selective epitaxial growth; performing chemical mechanical polishing to obtain the heterogeneously integrated semiconductor structure with Ge and a group III-V semiconductor material being coplanar; removing the spacer and a defect part of the Ge layer close to the spacer; implementing isolation between Ge and the group III-V semiconductor material; and preparing a Ge channel PMOS and a group III-V channel NMOS by forming an MOS structure. Therefore, by using the method for preparing heterogeneously integrated semiconductor structure with a hybrid of Ge and a group III-V semiconductor material coplanar on a bulk silicon substrate according to the present invention, the CMOS device with high performance is implemented on the substrate structure with a hybrid of Ge and the group III-V semiconductor material coplanar.

Preferably, in the method for preparing a heterogeneously integrated semiconductor structure with a hybrid of Ge and a group III-V semiconductor material mixed and coplanar on a bulk silicon substrate, the group III-V semiconductor material layer comprises materials such as GaAs, AlAs, AlGaAs, InGaAs, or the like.

Preferably, in the method for preparing a heterogeneously integrated semiconductor structure with a hybrid of Ge and a group III-V semiconductor material coplanar on a bulk silicon substrate, the spacer is a silicon dioxide spacer or a silicon nitride spacer.

Preferably, in the method for preparing a heterogeneously integrated semiconductor structure with a hybrid of Ge and a group III-V semiconductor material coplanar on a bulk silicon substrate, the epitaxy technology or a bonding technology is used in the step of preparing the Ge semiconductor layer on the bulk silicon substrate.

Preferably, in the method for preparing a heterogeneously integrated semiconductor structure with a hybrid of Ge and a group III-V semiconductor material coplanar on a bulk silicon substrate, the epitaxy technology or the bonding technology is adopted in the step of preparing the group III-V semiconductor material layer on the Ge semiconductor layer.

Preferably, in the method for preparing a heterogeneously integrated semiconductor structure with a hybrid of Ge and a group III-V semiconductor material coplanar on a bulk silicon substrate, the shallow trench isolation technology is adopted in the step of removing the spacer and the defect part of the Ge layer close to the spacer. Further preferably, the second photolithography is performed in the shallow trench isolation technology.

Preferably, in the method for preparing a heterogeneously integrated semiconductor structure with a hybrid of Ge and a group III-V semiconductor material coplanar on a bulk silicon substrate, silicon dioxide is adopted in the step of implementing the isolation between Ge and the group III-V semiconductor material to isolate Ge from the group III-V semiconductor material. Further preferably, the deposition of silicon dioxide is implemented through the high density plasma deposition technology.

According to a second aspect of the present invention, provided is a high performance CMOS device manufactured according to the method that is described in the first aspect of the present invention, for preparing a heterogeneously integrated semiconductor structure with a hybrid of Ge and a group III-V semiconductor material coplanar on a bulk silicon substrate.

Since the method, described in the first aspect of the present invention, for preparing a heterogeneously integrated semiconductor structure with a hybrid of Ge and a group III-V semiconductor material mixed and coplanar on a bulk silicon substrate is adopted, persons skilled in the art should understand that, the CMOS device according to the second aspect of the present invention may also achieve the beneficial technical effects implemented through the method according to the first aspect of the present invention for preparing a heterogeneously integrated semiconductor structure with a hybrid of Ge and a group III-V semiconductor material mixed and coplanar on a bulk silicon substrate.

### BRIEF DESCRIPTION OF THE DRAWINGS

With reference to the accompanying drawings and the detailed description in the following, the present invention will be more completely understood, and the accompanying advantages and the features thereof will be more easily understood, where:

FIG. 1 is a flow chart of a method for manufacturing a CMOS device according to an embodiment of the present invention.

FIG. 2 is a schematic diagram of a semiconductor structure obtained after first step S0 shown in FIG. 1.

FIG. 3 is a schematic diagram of a semiconductor structure obtained after second step S1 shown in FIG. 1.

FIG. 4 is a schematic diagram of a semiconductor structure obtained after third step S2 shown in FIG. 1.

FIG. 5 is a schematic diagram of a semiconductor structure obtained after fourth step S3 shown in FIG. 1.

FIG. 6 is a schematic diagram of a semiconductor structure obtained after fifth step S4 shown in FIG. 1.

FIG. 7 is a schematic diagram of a semiconductor structure obtained after sixth step S5 shown in FIG. 1.

FIG. 8 is a schematic diagram of a semiconductor structure obtained after seventh step S6 shown in FIG. 1.

FIG. 9 is a schematic diagram of a semiconductor structure obtained after eighth step S7 shown in FIG. 1.

FIG. 10 is a schematic diagram of a semiconductor structure obtained after ninth step S8 shown in FIG. 1.

It should be noted that, the accompanying drawings are used to illustrate the present invention, but are not intended to limit the present invention. Attention should be paid to that, the accompanying drawings for representing the structure may not be drawn in proportion. Same or similar components are marked with same or similar marks in the accompanying drawings.

### DETAILED DESCRIPTION OF THE PREFERRED EMBODIMENTS

In order to make the content of the present invention clearer and more comprehensible, the content of the present invention is described in detail below with reference to specific embodiments and the accompanying drawings

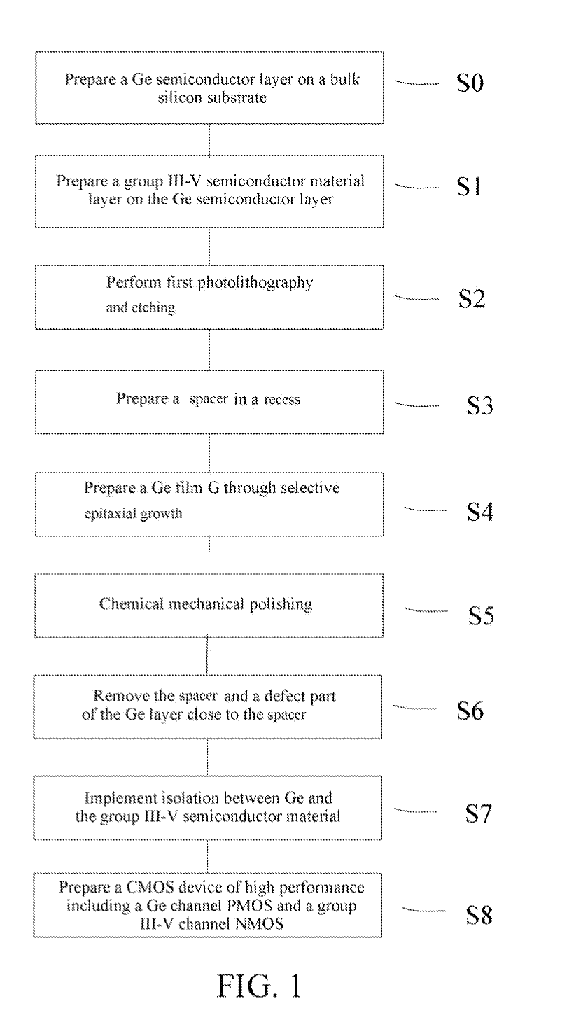

FIG. 1 is a flowchart of a method for preparing a heterogeneously integrated semiconductor structure with a hybrid of Ge and a group III-V semiconductor material coplanar on a bulk silicon substrate according to an embodiment of the present invention.

As shown in FIG. 1, the method for preparing the heterogeneously integrated semiconductor structure with a hybrid of Ge and the group III-V semiconductor material coplanar on a bulk silicon substrate according to the embodiment of the present invention includes the following steps.

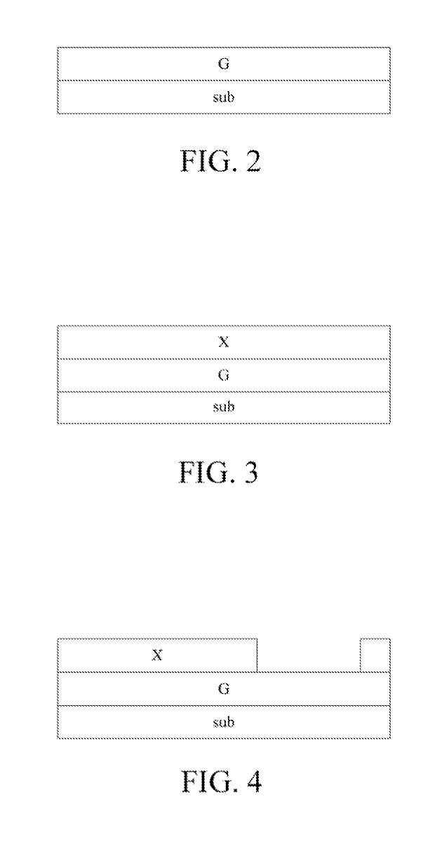

First step S0: Prepare a Ge semiconductor layer on a bulk silicon substrate Sub. More specifically, the step of preparing the Ge semiconductor layer on the bulk silicon substrate Sub may, for example, include forming a Ge semiconductor layer G on the bulk silicon substrate Sub through an epitaxy technology or a bonding technology. FIG. 2 is a schematic diagram of a semiconductor structure obtained after first step S0 shown in FIG. 1.

Second step S1: Prepare a group III-V semiconductor material layer X on the Ge semiconductor layer. FIG. 3 is a schematic diagram of a semiconductor structure obtained after second step S1 shown in FIG. 1. Preferably, the technology adopted in the step of preparing the group III-V semiconductor material layer X on the Ge semiconductor layer is the epitaxy technology or the bonding technology.

It should be noted that, the group III-V semiconductor material herein refers to a compound semiconductor material formed by a group III element (such as B, Al, Ga, or In) and a group V element (such as N, P, As, or Sb) in the periodic table of elements.

Preferably, in a specific example, the group III-V semiconductor material in the group III-V semiconductor material layer X includes, but is not limited to, GaAs, AlAs, AlGaAs, or InGaAs. Moreover, in the case that the group III semiconductor material is GaAs, AlAs, AlGaAs, or InGaAs, the performance of the CMOS device obtained is optimal.

Third step S2: Perform first photolithography and etching to make a patterned window to the Ge layer so as to form a recess; that is, in the first etching, the Ge layer G is used as a stop layer, and the etching is not performed on the Ge layer G. FIG. 4 is a schematic diagram of a semiconductor structure obtained after third step S2 shown in FIG. 1.

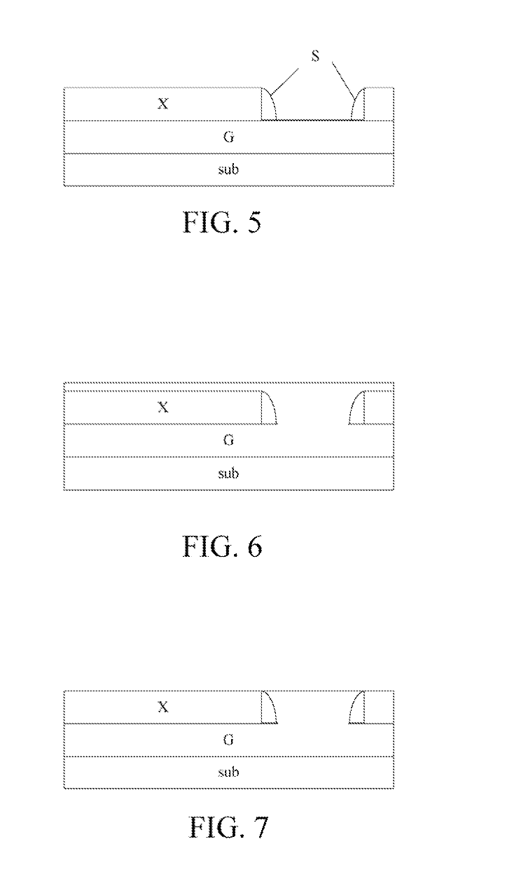

Fourth step S3: Prepare a spacer S in the recess. FIG. 5 is a schematic diagram of a semiconductor structure obtained after fourth step S3 shown in FIG. 1. Preferably, in a specific example, the spacer S is a silicon dioxide spacer or a silicon nitride spacer.

Fifth step S4: Prepare a Ge film G through selective epitaxial growth. FIG. 6 is a schematic diagram of a semiconductor structure obtained after fifth step S4 shown in FIG. 1.

Sixth step S5: Perform chemical mechanical polishing (CMP) to obtain a heterogeneously integrated semiconductor structure with a hybrid of Ge and the group III-V semiconductor material coplanar. FIG. 7 is a schematic diagram of a semiconductor structure obtained after sixth step S5 shown in FIG. 1.

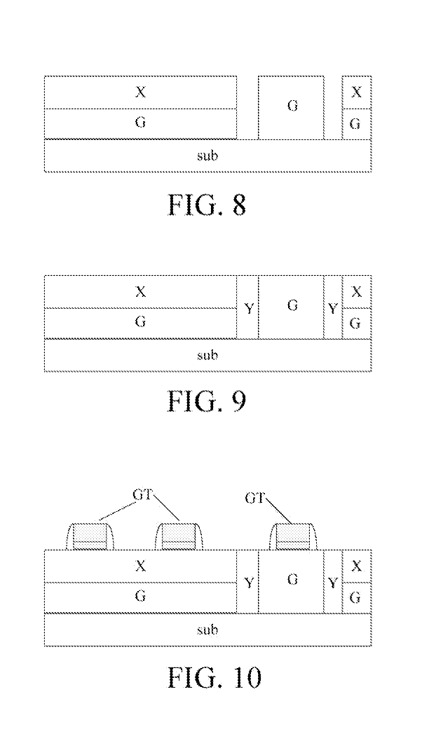

Seventh step S6: Remove the spacer and a defect part of the Ge layer close to the spacer. FIG. 8 is a schematic diagram of a semiconductor structure obtained after seventh step S6 shown in FIG. 1. Preferably, in a specific example, in the step of removing the spacer and the defect part of the Ge layer close to the spacer, a shallow trench isolation technology is adopted. Further preferably, second photolithography is performed in the shallow trench isolation technology.

It should be noted that, in the seventh step S6, a small trench is actually formed on the bulk silicon substrate sub, that is, an opening structure with the bulk silicon substrate Sub acting as a bottom.

Eighth step S7: implementing isolation Y between Ge and the group III-V semiconductor material. FIG. 9 is a schematic diagram of a semiconductor structure obtained after eighth step S7 shown in FIG. 1. Preferably, in a specific example, in the step of implementing the isolation Y between Ge and the group III-V semiconductor material, silicon dioxide is adopted as a isolation material Y to implement the isolation between Ge and the group III-V semiconductor material. Further preferably, the silicon dioxide is implemented through high density plasma deposition technology.

Ninth step S8: Prepare a Ge channel PMOS and a group III-V channel NMOS by forming an MOS structure GT. A method for forming the MOS structure GT may be any proper method known in the art. In the present invention, the specific method or step for forming the MOS structure GT is not limited. Moreover, FIG. 10 shows three MOS structures GTs. The three MOS structures GTs are merely used for exemplification, but are not used to specifically limit the number and position interval between the MOS structures GTs in the present invention.

FIG. 10 is a schematic diagram of a semiconductor structure obtained after ninth step S8 shown in FIG. 1. It can be seen that, through step S0 to step S8, a CMOS device with high performance is implemented on a substrate structure with a hybrid of Ge and the group III-V semiconductor material coplanar according to the preparation method provided in the embodiment of the present invention.

Moreover, the method for preparing a heterogeneously integrated semiconductor structure with a hybrid of Ge and a group III-V semiconductor material coplanar on a bulk silicon substrate is particularly suitable for manufacturing a CMOS device in a node technology in 22 nm node technology or beyond. When the device characteristic dimension scales down to 22 nm or beyond, the CMOS device prepared through the method of preparation the heterogeneously integrated semiconductor structure with a hybrid of Ge and the group III-V semiconductor material mixed and coplanar on the bulk silicon substrate is especially superior to a CMOS device prepared through a method for manufacturing a CMOS device in the prior art.

According to another embodiment of the present invention, the present invention further relates to a CMOS device prepared according to a flow of the method for preparing the heterogeneously integrated semiconductor structure with a hybrid of Ge and the group III-V semiconductor material coplanar on the bulk silicon substrate shown in FIG. 1, such as a CMOS device located on a substrate structure with a hybrid of Ge and a group III-V semiconductor material coplanar shown in FIG. 9.

It should be understood that, although the present invention is described as the preferred embodiments, the foregoing embodiments are not intended to limit the present invention. Persons skilled in the art may make many possible variations or modifications to the technical solutions of the present invention or modify the embodiments as equivalent embodiments of equivalent changes according to the technical content disclosed in the foregoing without departing from the range of the technical solutions of the present invention. Therefore, any simple variation, equivalent change, and modification made to the foregoing embodiments according to the technical essence of the present invention without departing from the content of the technical solutions of the present invention still fall within the protection scope of the technical solutions of the present invention.

1. A heterogeneously integrated semiconductor substrate material of Ge and a group III-V semiconductor material coplanar on a bulk silicon substrate, wherein a silicone support substrate, a Ge semiconductor layer, a group III-V semiconductor material layer, and an isolation medium material between Ge and the group III-V semiconductor material are disposed;
the Ge semiconductor layer is located on the silicon support substrate, the group III-V semiconductor material layer is located on a part of the Ge semiconductor layer, and a top of the group III-V semiconductor material layer and a Ge semiconductor layer laterally adjacent to the group III-V semiconductor material layer are coplanar, the isolation medium material between Ge and the group III-V semiconductor material is located on the bulk silicon substrate, wherein a lateral structure is that two sides of the isolation medium material are connected to the Ge semiconductor layer and the group III-V semiconductor material respectively.

2. A semiconductor structure, comprising the substrate material as in claim 1, wherein at least two kinds of devices are comprised, and at least one of the devices is located on the Ge semiconductor layer, and the other device is located on the group III-V semiconductor material layer.

3. The semiconductor structure as in claim 2, wherein the device on the Ge semiconductor is PMOS, and the device on the group III-V semiconductor material layer is NMOS.

4. The semiconductor structure as in claim 2, a Ge semiconductor layer used for the PMOS device is a part of the Ge semiconductor layer exposed on a surface.

5. A preparation method of the substrate material as in claim 1, comprising the following steps:
(1) preparing a Ge semiconductor layer on a bulk silicon substrate;
(2) preparing a group III-V semiconductor material layer on a Ge semiconductor layer structure;
(3) performing first photolithography and etching to make a patterned window to a Ge layer so as to form a recess;
(4) preparing a spacer in the recess;
(5) preparing a Ge film through selective epitaxial growth;
(6) performing chemical mechanical polishing to obtain a heterogeneously integrated semiconductor structure with a hybrid of Ge and a group III-V semiconductor material coplanar;
(7) removing the spacer and a defect part of the Ge layer close to the spacer;
(8) implementing isolation between Ge and the group III-V semiconductor material; and
(9) preparing a Ge channel PMOS and a group III-V channel NMOS by forming a gate structure.

6. The substrate material as in claim 1, wherein the group III-V semiconductor material comprises GaAs, AlAs, AlGaAs, InGaAs, or the like.

7. The substrate material as in claim 1, wherein the group III-V semiconductor material is formed on the Ge semiconductor.

8. The substrate material as in claim 1, wherein the spacer is a silicon dioxide spacer or a silicon nitride spacer.

9. The substrate material as in claim 1, wherein in the step of preparing the Ge semiconductor layer on the bulk silicon substrate, an epitaxy technology or a bonding technology is adopted.

10. The substrate material as in claim 1, wherein in the step of preparing group III-V semiconductor material layer on the Ge semiconductor layer, an epitaxy technology or a bonding technology is adopted.

11. The substrate material as in claim 1, wherein in the step of removing the side wall and the defected part of the Ge layer close to the side wall, a shallow trench isolation technology is adopted.

12. The substrate material as in claim 1, wherein in the step of implementing the isolation between Ge and the group III-V semiconductor material, silicon dioxide is adopted to implement the isolation between Ge and the group III-V semiconductor material.

13. A preparation method of the semiconductor structure as in claim 2, comprising the following steps:
(1) preparing a Ge semiconductor layer on a bulk silicon substrate;
(2) preparing a group III-V semiconductor material layer on a Ge semiconductor layer structure;
(3) performing first photolithography and etching to make a patterned window to a Ge layer so as to form a recess;
(4) preparing a spacer in the recess;
(5) preparing a Ge film through selective epitaxial growth;
(6) performing chemical mechanical polishing to obtain a heterogeneously integrated semiconductor structure with a hybrid of Ge and a group III-V semiconductor material coplanar;
(7) removing the spacer and a defect part of the Ge layer close to the spacer;
(8) implementing isolation between Ge and the group III-V semiconductor material; and
(9) preparing a Ge channel PMOS and a group III-V channel NMOS by forming a gate structure.

14. The preparation method as in claim 5, wherein the group III-V semiconductor material comprises GaAs, AlAs, AlGaAs, InGaAs, or the like.

15. The preparation method as in claim 5, wherein the group III-V semiconductor material is formed on the Ge semiconductor.

16. The preparation method as in claim 5, wherein the spacer is a silicon dioxide spacer or a silicon nitride spacer.

17. The preparation method as in claim 5, wherein in the step of preparing the Ge semiconductor layer on the bulk silicon substrate, an epitaxy technology or a bonding technology is adopted.

18. The preparation method as in claim 5, wherein in the step of preparing group III-V semiconductor material layer on the Ge semiconductor layer, an epitaxy technology or a bonding technology is adopted.

19. The preparation method as in claim 5, wherein in the step of removing the side wall and the defected part of the Ge layer close to the side wall, a shallow trench isolation technology is adopted.

20. The preparation method as in claim 5, wherein in the step of implementing the isolation between Ge and the group III-V semiconductor material, silicon dioxide is adopted to implement the isolation between Ge and the group III-V semiconductor material.
